(19) United States
(12) Patent Application Publication
(10) Pub. No.: US 2016/0323996 A1
(43) Pub. Date: Nov. 3, 2016

(54) MULTILAYER CIRCUIT BOARD AND INSPECTION APPARATUS INCLUDING THE SAME

(71) Applicant: Murata Manufacturing Co., Ltd., Kyoto (JP)

(72) Inventor: Tadaji Takemura, Kyoto (JP)

(21) Appl. No.: 15/210,182

(22) Filed: Jul. 14, 2016

Related U.S. Application Data
(63) Continuation of application No. PCT/JP2015/050729, filed on Jan. 14, 2015.

(30) Foreign Application Priority Data
Jan. 17, 2014 (JP) 2014-006424

(51) Int. Cl. H05K 1/02; H05K 3/00; H05K 3/46; H05K 3/40; H05K 1/03

(52) U.S. Cl. CPC H05K 1/0298; H05K 3/4061; H05K 1/0306; H05K 3/4667; H05K 1/0353; H05K 1/0271; H05K 3/0047

(57) ABSTRACT

A multilayer circuit board 1 includes a ceramic multilayer body 2, in which a plurality of ceramic layers 2a to 2d are stacked, and a resin multilayer body 3 which is stacked on the ceramic multilayer body 2 and in which a plurality of resin insulating layers 3a to 3c are stacked, wherein the peripheral portion of the resin multilayer body 3 is thinner than the central portion. Consequently, residual stress that acts on the peripheral portion of the interface serving as a base point of interfacial peeling between the resin multilayer body 3 and the ceramic multilayer body 2 can be relaxed and, thereby, interfacial peeling between the resin multilayer body 3 and the ceramic multilayer body 2 can be reduced. Also, the volume of the resin insulating layer 3 decreases by making the peripheral portion of the resin insulating layer 3 thin.

### FIELD OF THE DISCLOSURE

The present disclosure relates to a multilayer circuit board composed of ceramic layers and resin insulating layers and an inspection apparatus including the multilayer circuit board.

### DESCRIPTION OF THE RELATED ART

Probe cards, in which probe pins are disposed on a ceramic multilayer substrate, have been widely adopted for electrical inspection of semiconductor elements, e.g., LSIs. Also, in recent years, the number of terminals has increased and the pitch of the terminals has decreased because of high integration of semiconductor elements and, thereby, multilayer circuit boards, in which some layers of the ceramic multilayer substrate have been replaced with resin insulating layers of polyimide or the like suitable for forming fine wires, have been used.

For example, a multilayer circuit board 100 described in Patent Document 1 has a structure, in which a ceramic multilayer body 101 produced by stacking a plurality of ceramic layers 101a and a resin multilayer body 102 produced by stacking a plurality of resin insulating layers 102a are included and the resin multilayer body 102 is stacked on the ceramic multilayer body 101, as shown in FIG. 13. In this regard, a plurality of surface electrodes 103 connected to their respective probe pins are disposed at a small pitch on the upper surface of the multilayer circuit board 100. Also, a plurality of back surface electrodes 104 are disposed on the lower surface of the multilayer circuit board 100 while having a one-to-one correspondence with the surface electrodes 103 and being connected to the corresponding surface electrodes 103. Each of back surface electrodes 104 is disposed so as to be connected to an external mounting substrate.

Meanwhile, a rewiring structure is disposed in the resin multilayer body 102 and the ceramic multilayer body 101 such that the pitch between adjacent back surface electrodes 104 is made larger than the pitch between adjacent surface electrodes 103.

Regarding formation of such a rewiring structure, the resin multilayer body 102 nearer to the surface electrode 103 includes the resin insulating layers 102a composed of polyimide or the like capable of forming fine wires because wires disposed inside the resin multilayer body 102 have to be made fine and the distance between adjacent wires has to be decreased. Also, the ceramic multilayer body 101, which has a relatively wide space for forming wires, includes ceramic layers 101a having a rigidity higher than the rigidity of the resin insulating layer 102a and having a coefficient of linear expansion close to the coefficient of linear expansion of an inspection medium, e.g., an IC wafer. The above-described configuration of the multilayer circuit board 100 makes it possible to electrically inspect the semiconductor elements in which the number of terminals has increased and the pitch between terminals has decreased in recent years.

Patent Document 1: Japanese Unexamined Patent Application Publication No. 2011-9694 (refer to paragraphs 0019 to 0022, FIG. 1, and the like)

### BRIEF SUMMARY OF THE DISCLOSURE

However, the multilayer circuit board 100 in the related art is formed so as to have a multilayer structure of the ceramic multilayer body 101 and the resin multilayer body 102. Therefore, for example, when the resin multilayer body 102 is formed on the ceramic multilayer body 101, residual stress is generated inside the multilayer circuit board 100 because of cure shrinkage of the resin multilayer body 102.

If residual stress is generated inside the multilayer circuit board 100, peeling may occur at the interface between the ceramic multilayer body 101 and the resin multilayer body 102 or warping of the multilayer circuit board 100 may occur. Also, if the flatness of the resin multilayer body 102 is degraded because of, for example, warping of the multilayer circuit board 100, wires disposed therein are bent and there is a problem that the resistance values of the wires may increase.

Meanwhile, the residual stress of the central portion in the resin multilayer body 102a is higher than the residual stress of the peripheral portion. Consequently, if an in-plane conductor is disposed on the resin insulating layer 102a located in the peripheral portion of the resin multilayer body 102, interfacial peeling between the in-plane conductor and the resin insulating layer 102 may occur. The possibility of occurrence of the interfacial peeling increases as the area of the in-plane conductor in plan view increases.

The present disclosure was made in consideration of the above-described problems. A first object is to reduce interfacial peeling between a resin multilayer body and a ceramic multilayer body and, in addition, reduce warping of a multilayer circuit board in the multilayer circuit board in which the resin multilayer body is stacked on the ceramic multilayer body. A second object is to reduce interfacial peeling of an in-plane conductor arranged in the peripheral portion of the resin multilayer body.

In order to achieve the above-described objects, a multilayer circuit board according to the present disclosure includes a ceramic multilayer body, in which a plurality of ceramic layers are stacked, and a resin multilayer body which is stacked on the ceramic multilayer body and in which a plurality of resin insulating layers are stacked, wherein the peripheral portion of the resin multilayer body is thinner than the central portion.

The resin multilayer body tends to shrink toward the center thereof during cure shrinkage and the amount of shrinkage increases with decreasing proximity to the center. In association with that, the shrinkage stress increases as well. Therefore, for example, at the interface between the ceramic multilayer body and the resin multilayer body, the residual stress in the multilayer circuit board due to cure shrinkage of the resin multilayer body acts on the peripheral portion strongly compared with the central portion. Consequently, in many cases, interfacial peeling between the ceramic multilayer body and the resin multilayer body occurs while the peripheral portion of the interface serves as the base point. Also, the shrinkage stress of the resin multilayer body increases in proportion to an increase in the volume of the resin multilayer body. Therefore, the residual stress in the multilayer circuit board increases in proportion to an increase in the volume of the resin multilayer body.

Then, interfacial peeling between the resin multilayer body and the ceramic multilayer body can be reduced by making the peripheral portion of the resin multilayer body thinner than the central portion because the residual stress that acts on the peripheral portion of the interface serving as a base point of interfacial peeling between the resin multilayer body and the ceramic multilayer body can be relaxed.

Also, the volume of the resin multilayer body decreases in the case where the peripheral portion of the resin multilayer body is made thin compared with the case where the resin multilayer body is configured to have a uniform thickness and, thereby, the residual stress resulting from cure shrinkage of the resin multilayer body is reduced. Consequently, warping of the multilayer circuit board can be reduced.

Meanwhile, the resin multilayer body may include a first multilayer portion, in which the plurality of resin insulating layers and a wiring layer having an in-plane conductor are stacked, and a second multilayer portion stacked on the center of the first multilayer portion, the wiring layer may be arranged between the predetermined adjacent resin insulating layers and, in addition, the in-plane conductor may be arranged in the peripheral portion of the resin multilayer body in plan view.

The close contact strength between the resin insulating layer and the in-plane conductor is less than the close contact strength between the resin insulating layers. Therefore, if the in-plane conductor is arranged in the peripheral portion, which has high residual stress associated with cure shrinkage of the resin insulating layer, of the resin multilayer body, interfacial peeling between the resin insulating layer and the in-plane conductor may occur. This interfacial peeling becomes remarkable as the area of the in-plane conductor increases. Here, the residual stress that acts on the peripheral portion of the resin multilayer body is reduced by decreasing the thickness of the peripheral portion of the resin multilayer body. Consequently, interfacial peeling between the resin insulating layer and the in-plane conductor can be reduced in the case where the in-plane conductor is arranged in the peripheral portion of the resin multilayer body.

Also, the flatness of the in-plane conductor is improved by forming the in-plane conductor on the resin insulating layer compared with the case where, for example, the in-plane conductor is formed on a ceramic multilayer body composed of a low-temperature co-fired ceramic (LTCC). Therefore, an increase in the resistance value and variations caused by degradation of flatness of the in-plane conductor can be suppressed.

Meanwhile, the resin multilayer body may include a first multilayer portion, in which the resin insulating layer and the wiring layer having the in-plane conductor are stacked, and a second multilayer portion stacked on the center of the first multilayer portion, the wiring layer may be arranged between the ceramic multilayer body and the resin insulating layer and, in addition, the in-plane conductor may be arranged in the peripheral portion of the resin multilayer body in plan view.

If the wiring layer of the resin multilayer body is arranged between the ceramic multilayer body and the resin insulating layer, there is a high possibility that the in-plane conductor arranged in the peripheral portion of the resin multilayer body peels at the interface to the ceramic multilayer body or the resin insulating layer. However, in the case where the thickness of the peripheral portion of the resin multilayer body decreases, the residual stress that acts on the peripheral portion of the resin multilayer body is reduced and, thereby, interfacial peeling between the ceramic multilayer body or the resin insulating layer and the in-plane conductor can be reduced in the case where the in-plane conductor is arranged in the peripheral portion of the resin multilayer body.

Also, the first multilayer portion may have a rectangular shape in plan view, and the in-plane conductor may be arranged between two adjacent corner portions of four corner portions of the first multilayer portion in plan view. In the case where the first multilayer portion has a rectangular shape in plan view, the residual stress of the first multilayer portion due to cure shrinkage of the resin multilayer body acts on the four corner portions most strongly. Then, peeling of the in-plane conductor can be reduced by arranging the in-plane conductor between two adjacent corner portions so as to avoid the four corner portions on which the stress acts strongly.

Also, the in-plane conductor may be configured to have a mesh pattern by being provided with a plurality of through holes penetrating the in-plane conductor in the thickness direction. Consequently, a resin of the resin insulating layer enters through holes in the in-plane conductor so as to set up pillars of the resin insulating layer during formation of the resin multilayer body. Then, peeling of the in-plane conductor can be reduced because the stress that acts on the interface between the resin insulating layer and the in-plane conductor and the interface between the ceramic multilayer body and the in-plane conductor is relaxed by the pillars.

Also, the wiring layer may have a plurality of in-plane conductors. In this case, interfacial peeling of each of the in-plane conductors and the resin insulating layer or the ceramic multilayer body can be reduced.

At least a pair of in-plane conductors of the plurality of in-plane conductors may be arranged at positions symmetric with respect to the central point of the first multilayer portion in plan view. The in-plane conductors have a function of suppressing cure shrinkage of the resin multilayer body. Therefore, for example, when the first multilayer portion is viewed from above, if the in-plane conductors are arranged at shifted positions with respect to the center of the first multilayer portion, the amount of shrinkage suppression of the portion provided with each of the in-plane conductors of the first multilayer portion is larger than the amount of shrinkage suppression of the portion opposite to the portion provided with each of the in-plane conductors of the first multilayer portion with respect to the above-described center. Consequently, unbalance of the amount of shrinkage suppression is generated in the first multilayer portion and, thereby, warping of the multilayer circuit board may occur. Then, warping of the multilayer circuit board can be reduced by arranging a pair of in-plane conductors at positions symmetric with respect to the central point of the first multilayer portion because the balance of the amount of shrinkage suppression between the portions provided with the above-described pair of in-plane conductors of the first multilayer portion is improved.

Also, the in-plane conductor may be a ground electrode or a power supply electrode. In this case, a specific configuration, in which the in-plane conductor is a ground electrode or a power supply electrode, can be provided.

Also, a part of the plurality of in-plane conductors may be ground electrodes and the remainder may be power supply electrodes. In this case, a specific configuration, in which the plurality of in-plane conductors are composed of ground electrodes and power supply electrodes, can be provided.

Also, the in-plane conductor may be configured to have a circular shape in plan view. For example, in the case where the in-plane conductor is configured to have a rectangular shape in plan view, the stress (residual stress) that acts on the interface between the in-plane conductor and the resin insulating layer or the ceramic layer concentrates on four corner portions and, thereby, peeling of the in-plane conductor occurs easily while the four corner portions serve as the base points. Then, interfacial peeling between the in-plane conductor and the resin insulating layer and between the in-plane conductor and the ceramic multilayer body can be reduced by making the in-plane conductor have a circular shape because the residual stress can be dispersed into the entire peripheral portion of the in-plane conductor.

Also, the in-plane conductor may be configured to have a polygonal shape in plan view. In this case, a specific configuration, in which the in-plane conductor has a polygonal shape in plan view, can be provided. In this regard, in the case where the shape of the in-plane conductor is specified as heptagonal or greater, the stress (residual stress) that acts on each corner can be reduced compared with the case where the in-plane conductor is rectangular. Therefore, interfacial peeling between the in-plane conductor and the resin insulating layer or the ceramic multilayer body can be reduced.

Also, the resin multilayer body in plan view may be configured to have an area smaller than the area of the ceramic multilayer body in plan view. The residual stress in the multilayer circuit board due to cure shrinkage of the resin multilayer body is in proportion to the area of the resin multilayer body in plan view. Consequently, interfacial peeling between the ceramic multilayer body and the resin multilayer body and warping of the multilayer circuit board can be reduced by making the area of the resin multilayer body in plan view smaller than the area of the ceramic multilayer body because the residual stress in the multilayer circuit board is reduced compared with the case where the areas of the two multilayer bodies in plan view are equalized.

Also, the resin multilayer body may further include another multilayer portion stacked on the second multilayer portion, and the resin multilayer body may be configured to have a pyramid shape, in which the first multilayer portion, the second multilayer portion, and the other multilayer portion are configured such that the area of an upper layer is smaller than the area of a lower layer in plan view.

In the case where the resin multilayer body includes another multilayer portion stacked on the second multilayer portion, the volume of the entire resin multilayer body can be decreased compared with the case where the other multilayer portion in plan view is made to have an area equal to the area of the second multilayer portion by making the area of the other multilayer portion in plan view smaller than the area of the second multilayer portion and making the resin multilayer body have a pyramid shape. Consequently, the residual stress, which is associated with cure shrinkage of the resin multilayer body, of the multilayer circuit board is reduced and, thereby, interfacial peeling between the ceramic multilayer body and the resin multilayer body and warping of the multilayer circuit board can be reduced.

Also, the multilayer circuit board may further include a plurality of upper surface electrodes disposed on the upper surface of the resin multilayer body and a plurality of lower surface electrodes disposed on the lower surface of the ceramic multilayer body so as to correspond to the plurality of upper surface electrodes and connected to the corresponding upper surface electrodes, wherein wiring structures in the ceramic multilayer body and the resin insulating layer may be configured such that the pitch between adjacent lower surface electrodes becomes larger than the pitch between adjacent upper surface electrodes. In this case, regarding the multilayer circuit board, in which a rewiring structure is disposed, each of interfacial peeling between the resin multilayer body and the ceramic multilayer body, warping of the multilayer circuit board, and an increase in the resistance value of the wires in the resin multilayer body caused by warping of the resin multilayer body can be reduced.

Also, the multilayer circuit board may be used for an inspection apparatus and that is configured to inspect a semiconductor. In this case, a probe card, in which each of interfacial peeling between the resin multilayer body and the ceramic multilayer body, warping of the multilayer circuit board, and an increase in the resistance value of the wires in the resin multilayer body caused by warping of the resin multilayer body is reduced, can be provided by connecting, for example, a probe pin to each of the upper surface side connection electrodes.

According to the present disclosure, interfacial peeling between the resin multilayer body and the ceramic multilayer body can be reduced by making the peripheral portion of the resin multilayer body thinner than the central portion because the residual stress that acts on the interface between the ceramic multilayer body and the resin multilayer body, in particular, the peripheral portion of the interface serving as a base point of interfacial peeling between the resin multilayer body and the ceramic multilayer body can be relaxed.

Also, the volume of the resin multilayer body decreases in the case where the peripheral portion of the resin multilayer body is made thin compared with the case where the resin multilayer body is configured to have a uniform thickness and, thereby, the residual stress associated with cure shrinkage of the resin multilayer body is reduced. Consequently, warping of the multilayer circuit board can be reduced.

### BRIEF DESCRIPTION OF THE SEVERAL VIEWS OF THE DRAWINGS

FIG. 1 is a sectional view of a multilayer circuit board according to a first embodiment of the present disclosure.

FIG. 2 is a plan view of the multilayer circuit board shown in FIG. 1.

FIG. 3 is a sectional view of a multilayer circuit board according to a second embodiment of the present disclosure.

FIG. 4 is a plan view of a multilayer circuit board according to a third embodiment of the present disclosure.

FIG. 5 is a plan view of a multilayer circuit board according to a fourth embodiment of the present disclosure.

FIG. 6 is a plan view of a multilayer circuit board according to a fifth embodiment of the present disclosure.

FIG. 7 is a plan view of a multilayer circuit board according to a sixth embodiment of the present disclosure.

FIG. 8 is a plan view of a multilayer circuit board according to a seventh embodiment of the present disclosure.

FIG. 9 is a diagram illustrating a modified example of in-plane conductors shown in FIG. 8.

FIG. 10 is a plan view of a multilayer circuit board according to an eighth embodiment of the present disclosure.

FIG. 11 is a plan view of a multilayer circuit board according to a ninth embodiment of the present disclosure.

FIG. 12 is a plan view of a multilayer circuit board according to a tenth embodiment of the present disclosure.

FIG. 13 is a sectional view of a multilayer circuit board in the related art.

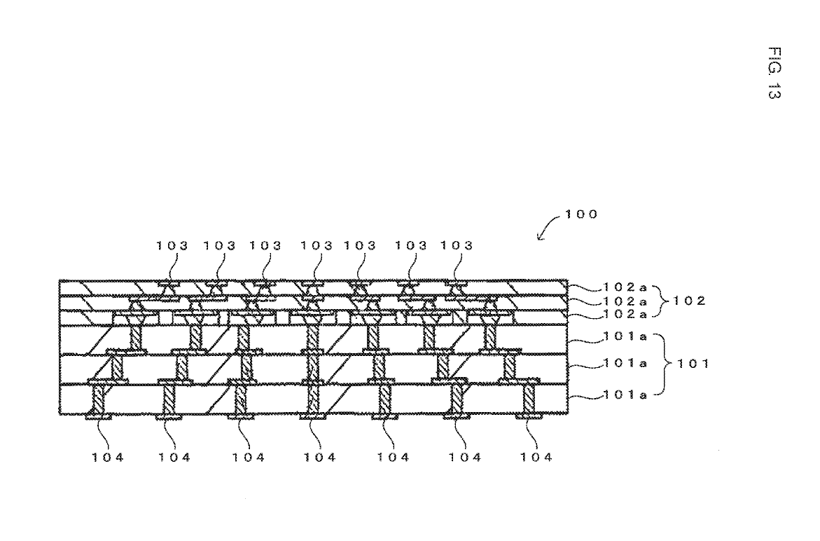

### DETAILED DESCRIPTION OF THE DISCLOSURE

### First Embodiment

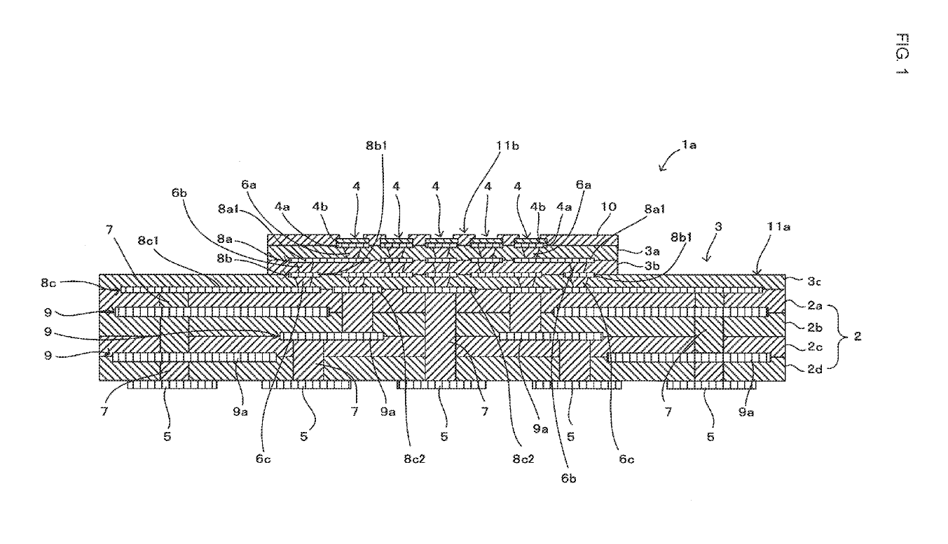

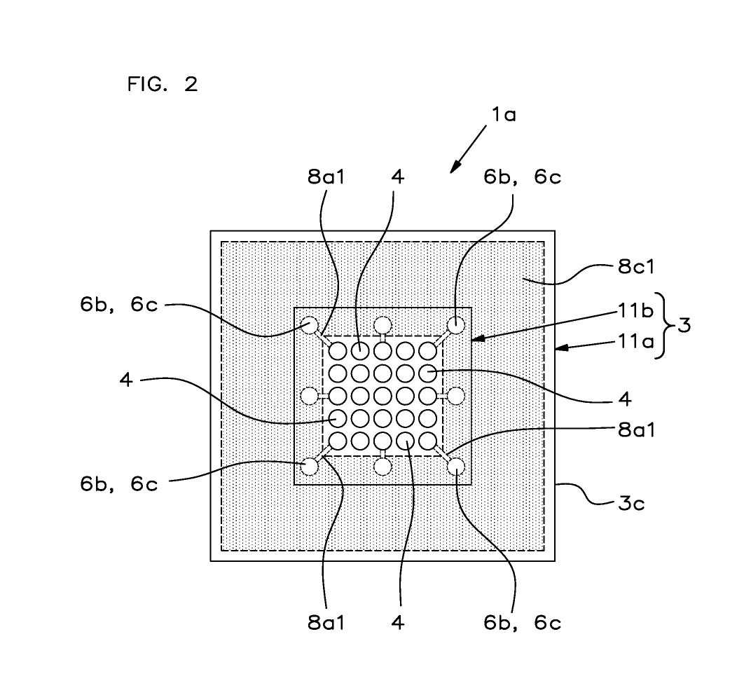

A multilayer circuit board 1a according to a first embodiment of the present disclosure will be described with reference to FIG. 1 and FIG. 2. In this regard, FIG. 1 is a sectional view of the multilayer circuit board 1a and FIG. 2 is a plan view of the multilayer circuit board 1a. In FIG. 2, for the sake of simplicity of explanations, only parts related to the present disclosure are shown, and other parts are not shown in the drawing.

As shown in FIG. 1, the multilayer circuit board 1a according to the present embodiment includes a ceramic multilayer body 2, in which a plurality of ceramic layers 2a to 2d are stacked, and a resin multilayer body 3, which is stacked on the ceramic multilayer body 2 and in which a plurality of resin insulating layers 3a to 3c are stacked. In addition, a plurality of upper surface electrodes 4 are disposed on the uppermost resin insulating layer 3a of the resin multilayer body 3. Further, a solder resist 10 for covering the peripheral portion of each of the upper surface electrodes 4 and the resin insulating layer 3a is disposed on the resin insulating layer 3a so as to expose the upper surface of each of the upper surface electrodes 4. Also, a plurality of lower surface electrodes 5 are disposed on the lower surface of the lowermost ceramic layer 2d of the ceramic multilayer body 2, serving as the lower surface of the multilayer circuit board 1a, so as to correspond to the upper surface electrodes 4 and connected to the corresponding upper surface electrodes 4. In this regard, the same resin insulating layer as each of the resin insulating layers 3a to 3c constituting the resin multilayer body 3 may be disposed in place of the solder resist 10.

In the ceramic multilayer body 2, the ceramic layers 2a to 2d and wiring layers 9 having in-plane conductors 9a are stacked alternately, and predetermined in-plane conductors 9a are connected to each other with via conductors 7 interposed therebetween. Here, a ceramic green sheet composed of a low-temperature co-fired ceramic (LTCC), in which the primary component is a ceramic (for example, alumina) containing borosilicate glass, can be used for each of the ceramic layers 2a to 2d. Also, various ceramic materials such as a high-temperature co-fired ceramic (HTCC), e.g., alumina, can be used as other materials constituting each of the ceramic layers 2a to 2d.

The in-plane conductors 9a disposed inside the ceramic multilayer body 2 are formed on the respective predetermined principal surfaces of the ceramic layers 2a to 2d by, for example, a printing technology using an electrically conductive paste containing a metal, e.g., Ag, Al, or Cu. In this regard, in the present embodiment, each of the in-plane conductors 9a is composed of Ag.

The via conductors 7 disposed inside the ceramic multilayer body 2 are formed by, for example, filling the through holes, which are formed in the ceramic layers 2a to 2d by using a laser or the like, with an electrically conductive paste containing any one of Ag, Al, Cu, and the like.

The lower surface electrodes 5 disposed on the lower surface of the ceramic multilayer body 2 are formed by, for example, a printing technology using an electrically conductive paste containing a metal, e.g., Ag, Al, or Cu. In this regard, Ni/Au plating may be further applied to the surface of each of the lower surface electrodes 5.

The ceramic multilayer body 2 may have the configuration, in which shrinkage suppression layers for suppressing shrinkage during firing of the ceramic layers 2a to 2d are arranged between adjacent ceramic layers 2a to 2d. Ceramic materials that do not shrink at the firing temperature of the ceramic layers 2a to 2d can be used for the shrinkage suppression layers. Consequently, warping of the ceramic multilayer body 2 after the firing is reduced and, thereby, warping of the multilayer circuit board 1a is reduced.

In the resin multilayer body 3, resin insulating layers 3a to 3c and wiring layers 8a to 8c including in-plane conductors 8a1, 8b1, 8c1, and 8c2 are stacked alternately, and predetermined in-plane conductors 8a1, 8b1, 8c1, and 8c2 are connected to each other with via conductors 6a to 6c interposed therebetween. Here, each of the resin insulating layers 3a to 3c is composed of a thermosetting resin, e.g., a polyimide or a glass epoxy resin. At this time, the Young's modulus of each of the ceramic layers 2a to 2d is about 220 GPa, whereas the Young's modulus of each of the resin insulating layers 3a to 3c composed of, for example, a polyimide is 1 to 5 GPa. Therefore, the Young's modulus of each of the resin insulating layers 3a to 3c is smaller than the Young's modulus of each of the ceramic layers 2a to 2d.

Also, the resin multilayer body 3 is composed of a first multilayer portion 11a, in which the resin insulating layer 3c serving as the lowermost layer and the wiring layer 8c including the in-plane conductors 8c1 and 8c2 are stacked and which is stacked on the ceramic multilayer body 2, and a second multilayer portion 11b, in which other resin insulating layers 3a and 3b and a plurality of wiring layers 8a and 8b are stacked and which is stacked on the center of the first multilayer portion. At this time, the first multilayer portion 11a is configured to have an area, in plan view, nearly equal to the area of the ceramic multilayer body 2 in plan view and, in addition, the second multilayer portion 11b is configured to have an area, in plan view, smaller than the area of the first multilayer portion 11a. In other words, the resin multilayer body 3 is configured such that the peripheral portion is thinner than the central portion.

In this regard, in the first multilayer portion 11a composed of the resin insulating layer 3c serving as the lowermost layer and the wiring layer 8c of the resin multilayer body 3, the wiring layer 8c is arranged between the ceramic multilayer body 2 and the resin insulating layer 3c. At this time, as shown in FIG. 2, each of the first multilayer portion 11a and the second multilayer portion 11b of the resin multilayer body 3 has a rectangular shape in plan view. Meanwhile, the predetermined in-plane conductor 8c1 (stippled area) included in the wiring layer 8c of the first multilayer portion 11a has the shape of a ring in plan view and is arranged in the peripheral portion of the resin multilayer body 3. Also, in the present embodiment, the in-plane conductor 8c1 is used as a ground electrode. Also, in the present embodiment, only one layer that is the resin insulating layer 3c is stacked on the wiring layer 8c, but at least two layers may be stacked. Also, the in-plane conductor 8c1 may be used as, for example, a power supply electrode.

Each of the upper surface electrodes 4 disposed on the upper surface of the resin multilayer body 3 includes an underlying electrode 4a composed of any one of metals of Cu, Ag, Al, and the like and a surface electrode 4b composed of Ni/Au plating.

Any one of metals of Cu, Ag, Al, and the like can be used as a material for forming each of the in-plane conductors 8a1, 8b1, 8c1, and 8c2 and the via conductors 6a to 6c, which are disposed in the resin multilayer body 3. Here, the in-plane conductors 8a1, 8b1, 8c1, and 8c2 are disposed on the respective predetermined principal surfaces of the resin insulating layers 3a to 3c.

Then, the upper surface electrode 4 and the lower surface electrode 5 corresponding thereto are connected to each other with the internal wires interposed therebetween, the internal wires including the plurality of via conductors 6a to 6c and 7 and the plurality of in-plane conductors 8a1, 8b1, 8c1, 8c2, and 9a disposed inside the resin multilayer body 3 and the ceramic multilayer body 2.

The pitch between adjacent lower surface electrodes 5 is set to be larger than the pitch between adjacent upper surface electrodes 4, and a rewiring structure is formed in the ceramic multilayer body 2 and the resin multilayer body 3 by the internal wires connecting the upper surface electrode 4 to the lower surface electrode 5 corresponding thereto.

The multilayer circuit board 1a having the above-described configuration is produced by preparing the ceramic multilayer body 2 first, and stacking the resin multilayer body 3 on the resulting ceramic multilayer body 2. Here, when the resin multilayer body 3 on the ceramic multilayer body 2 is cured, the residual stress due to cure shrinkage of the resin multilayer body 3 is generated in the multilayer circuit board 1a, and interfacial peeling between the ceramic multilayer body 2 and the resin multilayer body 3, warping of the multilayer circuit board 1a, and the like occur.

The interfacial peeling between the ceramic multilayer body 2 and the resin multilayer body 3 occurs because the close contact strength at the interface between the ceramic layer 2a and the resin insulating layer 3c, which are composed of different types of materials, is the lowest among the close contact strength at the interface between the adjacent ceramic layers 2a to 2d, the close contact strength at the interface between the adjacent resin insulating layers 3a to 3c, and the close contact strength at the interface between the adjacent ceramic layer 2a and the resin insulating layer 3c. In this regard, the resin multilayer body 3 tends to shrink toward the center thereof during cure shrinkage. The amount of shrinkage thereby increases with decreasing proximity to the center and, along with that, the shrinkage stress increases. Therefore, the above-described residual stress in the multilayer circuit board la due to cure shrinkage of the resin multilayer body 3 acts on, for example, the peripheral portion strongly compared with the central portion at the interface between the ceramic multilayer body 2 and the resin multilayer body 3. Consequently, interfacial peeling between the ceramic multilayer body 2 and the resin multilayer body 3 occurs while the peripheral portion of the interface serves as the base point, in many cases.

Also, as described above, the in-plane conductor 8c1 of the wiring layer 8c is arranged in the peripheral portion, on which the residual stress acts strongly, of the resin multilayer body 3. The in-plane conductor 8c1 is different from a linear conductor and is a solid ground electrode having a large area. Therefore, if such an in-plane conductor 8c1 is arranged in the peripheral portion of the resin multilayer body 3, there is a high possibility of occurrence of interfacial peeling between the in-plane conductor 8c1 and the ceramic layer 2a or interfacial peeling between the in-plane conductor 8c1 and the resin insulating layer 3c.

Then, the present embodiment is configured such that the residual stress, which acts on the interface between the ceramic multilayer body 2 and the resin multilayer body 3 and which is associated with cure shrinkage of the resin multilayer body 3, can be reduced by making the area of the second multilayer portion 11b in plan view smaller than the area of the first multilayer portion 11a and making the peripheral portion of the resin multilayer body 3 thinner than the central portion.

An inspection apparatus according to the present disclosure includes the above-described multilayer circuit board 1a and a plurality of probe pins connected to the upper surface electrodes 4 disposed on the upper surface of the multilayer circuit board 1a and is a probe card used in a wafer test for semiconductor elements (for example, LSIs) and the like before dicing. Specifically, the end of each probe pin of the probe card is brought into contact with a bonding pad of the LSI chip and, thereby, it is determined whether the electrical characteristics of the LSI chip are good or no good.

Next, a method for manufacturing the multilayer circuit board 1a will be described. In this regard, the manufacturing method described below can also be applied to multilayer circuit boards 1b to 1j according to other embodiments described later.

Initially, the ceramic multilayer body 2 is prepared. At this time, the ceramic multilayer body 2 is formed by stacking the ceramic layers 2a to 2d and the wiring layers 9, which are prepared individually, in a predetermined order and pressure-bonding and firing the stacked materials. Here, the via holes 7 are formed in the ceramic layers 2a to 2d by, for example, forming via holes in the ceramic layers 2a to 2d by laser machining and filling the via holes with an electrically conductive paste containing any one of metals of Cu, Ag, and Al by the printing technology. Also, the in-plane electrodes 9a disposed on the principal surfaces of the ceramic layers 2a to 2d and the lower surface electrodes 5 can be formed by the printing technology using an electrically conductive paste containing any one of metals of Cu, Ag, and Al (Ag in the present embodiment).

Subsequently, the ceramic multilayer body 2 is subjected to double-sided polishing so as to enhance the flatness of the ceramic multilayer body 2, and each of the in-plane conductors 8c1 and 8c2 of the wiring layer 8c are formed on the resulting ceramic multilayer body 2. At this time, each of the in-plane conductors 8c1 and 8c2 can be formed by, for example, forming a Ti film serving as an underlying electrode on the ceramic multilayer body 2 by sputtering or the like, forming likewise a Cu film on the Ti film by sputtering or the like, and forming likewise a Cu film on the Cu film by electrolytic plating or electroless plating. In this regard, an increase in the resistance value resulting from bending of in-plane conductors 8a1, 8b1, 8c1 and 8c2 during sputtering and plating can be reduced by enhancing the flatness of the ceramic multilayer body 2 because of the above-described double-sided polishing.

Then, the resin insulating layer 3c is formed on the ceramic multilayer body 2 provided with each of the in-plane conductors 8c1 and 8c2 by, for example, application of polyimide by spin coating or the like. Also, via conductors 6c are formed in the resin insulating layer 3c by photolithography and heat curing is performed so as to form the first multilayer portion 11a of the resin insulating layer 3.

Thereafter, the wiring layer 8b including in-plane conductors 8b1 is formed on the resin insulating layer 3c. The in-plane conductor 8b1 can be formed by forming a Ti film serving as an underlying electrode by sputtering or the like, forming likewise a Cu film on the Ti film by sputtering or the like, and forming likewise a Cu film on the Cu film by electrolytic plating or electroless plating.

Subsequently, the resin insulating layer 3b is formed on the resin insulating layer 3c provided with the wiring layer 8b by, for example, application of polyimide by spin coating or the like. At this time, the resin insulating layer 3 is configured to have an area in plan view smaller than the area of the resin insulating layer 3c (first multilayer portion 11a) and is arranged in the central portion of the upper surface of the resin insulating layer 3c. The via conductors 6b in the resin insulating layer 3b can be formed by the same method as the method for forming the via conductors 6c in the resin insulating layer 3c.

The resin insulating layer 3a serving as the uppermost layer, the wiring layer 8a, and the via conductors 6a can be formed in the same manner as that in the case of the resin insulating layer 3b.

Thereafter, the second multilayer portion 11b of the resin multilayer body 3 is formed on the resin insulating layer 3a by forming each of the underlying electrodes 4a in the same manner as that of the in-plane conductors 8a1 and 8b1 and forming each of the upper surface electrodes 4b on the underlying electrode 4a by applying Ni/Au plating.

Then, the solder resist 10 is formed on the resin insulating layer 3a by, for example, applying polyimide by spin coating or the like and performing heat curing. Finally, each of the lower surface electrodes 5 are formed by forming each of the underlying electrodes on the lower surface of the ceramic multilayer body 2 and applying Ni/Au plating to these underlying electrodes and, thereby, the multilayer circuit board 1a is completed.

In the case where the resin multilayer body 3 is formed as described above, fine patterns of each of the upper surface electrodes 4 and each of the in-plane conductors 8a1 and 8b1 can be formed compared with the in-plane conductors 9a formed on the ceramic multilayer body 2 by using the printing technology.

Therefore, according to the above-described embodiment, interfacial peeling between the resin multilayer body 3 and the ceramic multilayer body 2 can be reduced by making the peripheral portion of the resin multilayer body 3 thinner than the central portion because the residual stress that acts on the interface between the ceramic multilayer body 2 and the resin multilayer body 3, in particular, the peripheral portion of the interface serving as a base point of interfacial peeling between the resin multilayer body 3 and the ceramic multilayer body 2 and that is caused by cure shrinkage of the resin multilayer body 3 can be relaxed.

Also, in the case where the peripheral portion of the resin multilayer body 3 is made thin, the volume of the resin multilayer body 3 decreases compared with the case where the resin multilayer body 3 is configured to have a uniform thickness and, thereby, the residual stress generated by cure shrinkage of the resin multilayer body 3 is reduced. Consequently, warping of the multilayer circuit board 1a can be reduced.

Also, the flatness of each of the in-plane conductors 8a1, 8b1, 8c1 and 8c2 disposed in the resin multilayer body 3 is enhanced by reduction in warping of the multilayer circuit board 1a. Therefore, an increase in the resistance value resulting from bending of each of the in-plane conductors 8a1, 8b1, 8c1 and 8c2 can be reduced.

Meanwhile, the close contact strength between the in-plane conductors 8a1, 8b1, 8c1 and 8c2 composed of a metal of Cu or the like and the ceramic layers 2a to 2d or the resin insulating layers 3a to 3c is low compared with the close contact strength between the resin insulating layers 3a to 3c and the close contact strength between the ceramic layers 2a to 2d. Therefore, the in-plane conductor 8c1 of the first multilayer portion 11a arranged in the peripheral portion of the resin multilayer body 3, on which the residual stress generated by cure shrinkage acts strongly, peels easily at the interface to resin insulating layer 3c or the interface to the ceramic layer 2a. However, in the present embodiment, interfacial peeling between the in-plane conductor 8c1 and the ceramic layer 2a or the resin insulating layer 3c can be reduced because the residual stress that acts on the peripheral portion of the resin multilayer body 3 can be reduced by decreasing the thickness of the peripheral portion of the resin multilayer body 3.

Also, if the area of the in-plane conductor 8c1 increases, the close contact strength between the in-plane conductor 8c1 and the ceramic layer 2a or the resin insulating layer 3c is reduced, and peeling occurs easily at the interface easily. Therefore, if the in-plane conductor 8c1 is formed as a ground electrode having a large area, as in the present embodiment, there is a high possibility of interfacial peeling. Also, if such an in-plane conductor 8c1 is arranged in the peripheral portion of the resin multilayer body 3, on which the residual stress acts strongly, the possibility of interfacial peeling further increases. However, according to the present embodiment, the residual stress that acts on the peripheral portion of the resin multilayer body 3 can be relaxed and, therefore, interfacial peeling between the in-plane conductor 8c1 and the ceramic layer 2a or the resin insulating layer 3c can be suppressed even in the case where the in-plane conductor 8c1 having a large area is arranged in the peripheral portion of the resin multilayer body 3.

Also, each of the resin insulating layers 3a to 3c is composed of a thermosetting resin having a small Young's modulus (for example, polyimide). Therefore, it is possible that action of the residual stress in the resin multilayer body 3 is not concentrated on the interface between the resin multilayer body 3 and the ceramic multilayer body 2 but is dispersed into the entire resin multilayer body 3. Consequently, interfacial peeling between the resin multilayer body 3 and the ceramic multilayer body 2 can be reduced.

Also, in the multilayer circuit board 1a according to the present embodiment, a rewiring structure is disposed inside the ceramic multilayer body 2 and the resin multilayer body 3 such that the pitch between adjacent lower surface electrodes 5 becomes larger than the pitch between adjacent upper surface electrodes 4. Here, the upper surface electrodes 4 arranged at a narrow pitch are disposed on the resin multilayer body 3 side in which fine wires are formed easily.

Also, interfacial peeling between the ceramic multilayer body 2 and the resin multilayer body 3 and warping of the multilayer circuit board 1a, which are harmful effects in the case where the multilayer circuit board 1a is configured to include the ceramic multilayer body 2 and the resin multilayer body 3, are reduced by making the peripheral portion of the resin multilayer body 3 thinner than the central portion. Consequently, the multilayer circuit board 1a is suitable for a substrate used in a probe card for performing an electrical inspection of semiconductor elements in recent years, where pitches of terminals have decreased.

Also, each of the ceramic layers 2a is composed of a low-temperature co-fired ceramic (ceramic green sheet), in which the primary component is a ceramic containing borosilicate glass, and therefore, a low resistance conductor, e.g., Ag, can be used for the wiring electrode, e.g., the in-plane conductor, disposed in the ceramic multilayer body 2.

### Second Embodiment

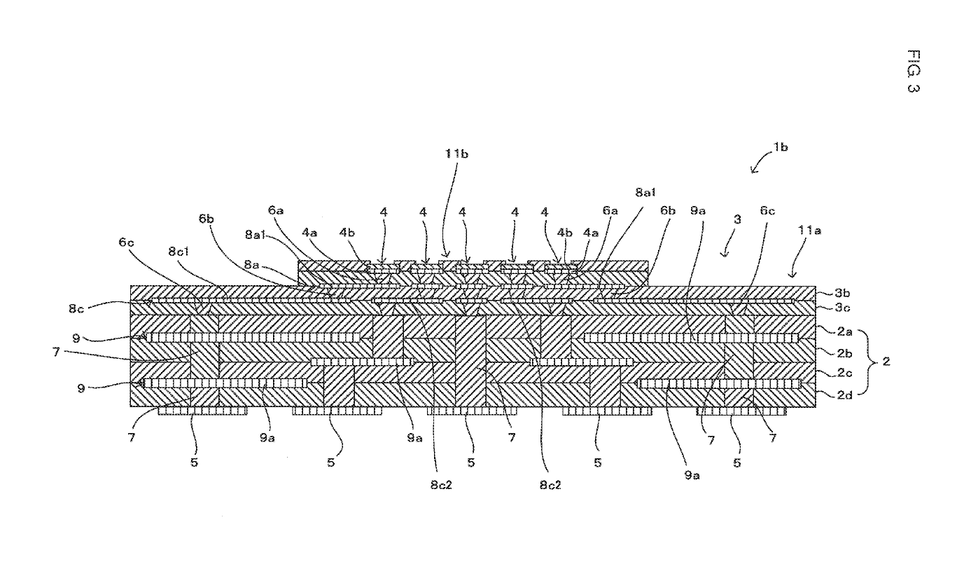

A multilayer circuit board 1b according to a second embodiment of the present disclosure will be described with reference to FIG. 3. In this regard, FIG. 3 is a sectional view of the multilayer circuit board 1b.

The multilayer circuit board 1b according to the present embodiment is different from the multilayer circuit board 1a according to the first embodiment described with reference to FIG. 1 in that, as shown in FIG. 3, the first multilayer portion 11a of the resin multilayer body 3 includes a plurality of (two in the present embodiment) resin insulating layers 3b and 3c, and a wiring layer 8c is arranged between these resin insulating layers 3b and 3c. Other configurations are the same as or corresponding to those of the multilayer circuit board 1a according to the first embodiment and, therefore, are indicated by the same reference numerals, and explanations thereof will not be provided.

In the multilayer circuit board 1a according to the first embodiment, the resin insulating layer 3b on the resin insulating layer 3c, which is the lowermost layer of the resin multilayer body 3, is formed as the second multilayer portion of the resin multilayer body 3. However, in the present embodiment, the resin insulating layer 3b is configured to have an area in plan view nearly equal to the area of the resin insulating layer 3c (first multilayer portion 11a) and is arranged as the resin insulating layer 3b of the first multilayer portion 11a. Then, the wiring layer 8c of the first multilayer portion 11a is arranged between two resin insulating layers 3b and 3c of the first multilayer portion 11a.

In the case where the in-plane conductors 8c1 and 8c2 are arranged between the two resin insulating layers 3b and 3c, as described above, the flatness of the in-plane conductors 8c1 and 8c2 is enhanced compared with the case where the in-plane conductors 8c1 and 8c2 are arranged between the ceramic multilayer body 2 composed of the low-temperature co-fired ceramic (LTCC) and the resin insulating layer 3c, as in the first embodiment. Consequently, in addition to the effects of the multilayer circuit board 1a according to the first embodiment, an increase in the resistance value and variations resulting from degradation of the flatness of the in-plane conductors 8c1 and 8c2 can be suppressed.

### Third Embodiment

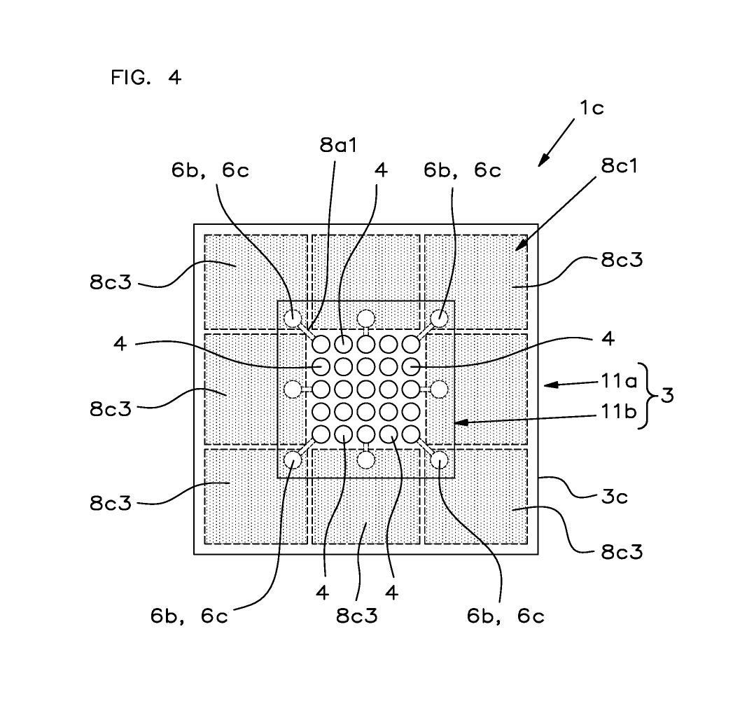

A multilayer circuit board 1c according to a third embodiment of the present disclosure will be described with reference to FIG. 4. In this regard, FIG. 4 is a plan view of the multilayer circuit board 1c and is a drawing corresponding to FIG. 2.

The multilayer circuit board 1c according to the present embodiment is different from the multilayer circuit board 1a according to the first embodiment described with reference to FIG. 1 and FIG. 2 in that, as shown in FIG. 4, the in-plane conductor 8c1 of the first multilayer portion 11a arranged in the peripheral portion of the resin multilayer body 3 is divided into a plurality of in-plane conductors 8c3 having a rectangular shape in plan view. Other configurations are the same as those of the multilayer circuit board 1a according to the first embodiment and, therefore, are indicated by the same reference numerals, and explanations thereof will not be provided.

As described above, the close contact strength between the in-plane conductor 8c1 and the ceramic layer 2a or the resin insulating layer 3c is reduced as the area of the in-plane conductor 8c1 in plan view increases. Therefore, if the in-plane conductor 8c1 serving as the ground electrode is formed as one electrode having a large area such as the in-plane conductor 8c1 in the first embodiment, the possibility of peeling at the interface to the ceramic layer 2a or the resin insulating layer 3c increases. Then, the in-plane conductor 8c1 is configured to be divided into a plurality of in-plane conductors 8c3 such that the area of each of the in-plane conductors 8c3 is made small and, thereby, interfacial peeling between each of the in-plane conductors 8c3 and the ceramic layer 2a or the resin insulating layer 3c can be reduced.

Also, a predetermined pair of in-plane conductors 8c3 among the in-plane conductors 8c3 are arranged at positions symmetric with respect to the central point of the first multilayer portion 11a in plan view. Here, each of the in-plane conductors 8c3 has a function of suppressing cure shrinkage of the resin multilayer body 3. Therefore, for example, when the first multilayer portion 11a is viewed from above, if the in-plane conductors 8c3 are arranged at shifted positions with respect to the center of the first multilayer portion 11a, the amount of shrinkage suppression of the portion provided with each of the in-plane conductors 8c3 of the first multilayer portion 11a is larger than the amount of shrinkage suppression of the portion opposite to the portion provided with each of the in-plane conductors 8c3 of the first multilayer portion 11a with respect to the above-described center. Consequently, unbalance of the amount of shrinkage suppression is generated in the first multilayer portion 11a and, thereby, warping of the multilayer circuit board 1c may occur. Then, warping of the multilayer circuit board 1c can be reduced by arranging the predetermined pair of in-plane conductors 8c3 at positions symmetric with respect to the central point of the first multilayer portion 11a because the balance of the amount of shrinkage suppression between the portions provided with the above-described pair of in-plane conductors 8c3 of the first multilayer portion 11a is improved.

In this regard, in the present embodiment, the case where each of the in-plane conductors 8c3 is the ground electrode is described. However, for example, a part of the in-plane conductors 8c3 may be ground electrodes and the remainder may be power supply electrodes.

### Fourth Embodiment

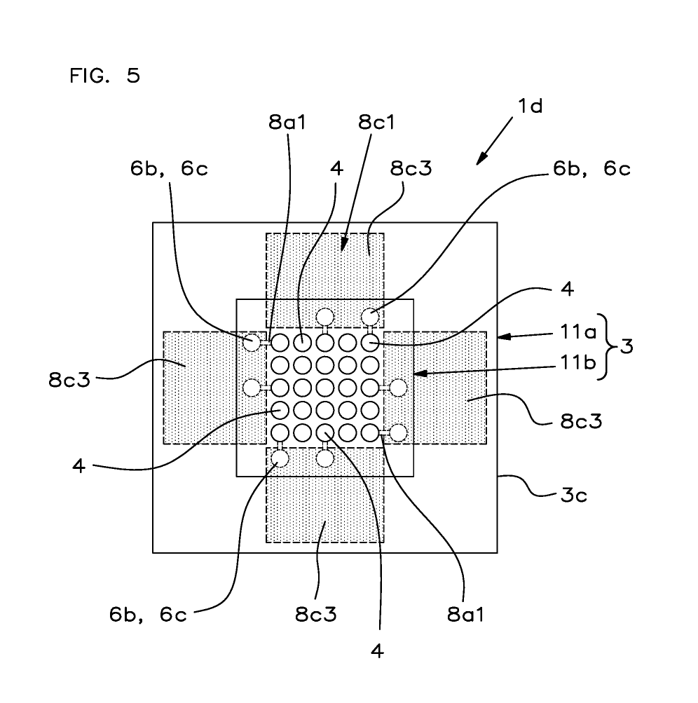

A multilayer circuit board 1d according to a fourth embodiment of the present disclosure will be described with reference to FIG. 5. In this regard, FIG. 5 is a plan view of the multilayer circuit board 1d and is a drawing corresponding to FIG. 2.

The multilayer circuit board 1d according to the present embodiment is different from the multilayer circuit board 1c according to the third embodiment described with reference to FIG. 4 in that, as shown in FIG. 5, each of the in-plane conductors 8c3 formed by dividing the in-plane conductor 8c1 is arranged between two adjacent corner portions of the four corner portions of the first multilayer portion having a rectangular shape in plan view. Other configurations are the same as those of the multilayer circuit board 1c according to the third embodiment and, therefore, are indicated by the same reference numerals, and explanations thereof will not be provided.

In the case where the first multilayer portion 11a has a rectangular shape in plan view, the residual stress generated by cure shrinkage of the resin multilayer body 3 acts on the four corner portions most strongly. Then, peeling of each of the in-plane conductors 8c3 from the ceramic layer 2a or the resin insulating layer 3c can be reduced by arranging each of the in-plane conductors 8c3 between two adjacent corner portions so as to avoid the four corner portions, on which the stress acts strongly, of the first multilayer portion 11a.

### Fifth Embodiment

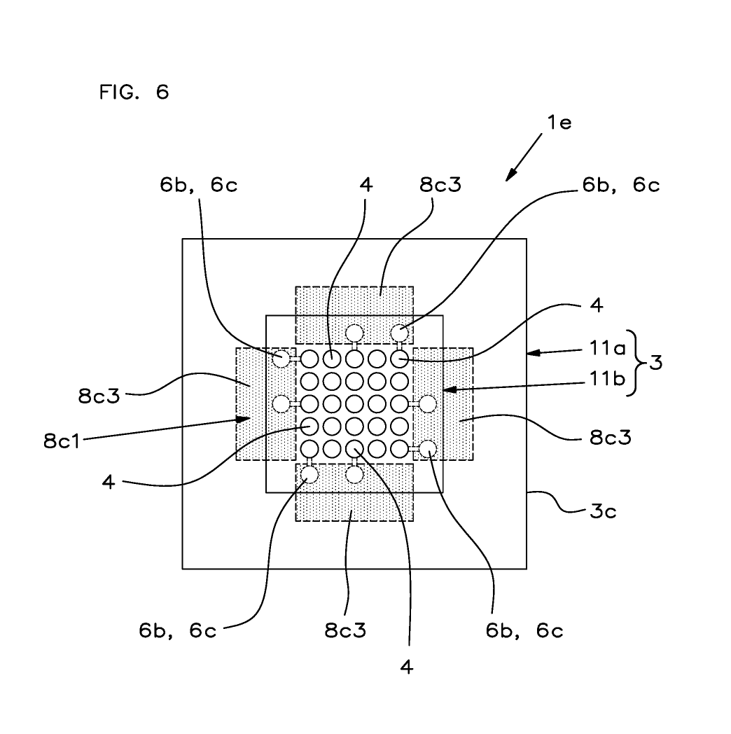

A multilayer circuit board he according to a fifth embodiment of the present disclosure will be described with reference to FIG. 6. In this regard, FIG. 6 is a plan view of the multilayer circuit board he and is a drawing corresponding to FIG. 2.

The multilayer circuit board he according to the present embodiment is different from the multilayer circuit board 1d according to the fourth embodiment described with reference to FIG. 5 in that, as shown in FIG. 6, each of the in-plane conductors 8c3 is disposed at a position apart from the peripheral edge of the first multilayer portion 11a. Other configurations are the same as those of the multilayer circuit board 1d according to the fourth embodiment and, therefore, are indicated by the same reference numerals, and explanations thereof will not be provided.

The residual stress in the first multilayer portion 11a based on cure shrinkage of the resin multilayer body 3 increases with increasing proximity to the peripheral edge from the center in plan view. Therefore, peeling of each of the in-plane conductors 8c3 from the ceramic layer 2a and the resin insulating layer 3c can be further reduced by disposing each of the in-plane conductors 8c3 at a position apart from the peripheral edge of the first multilayer portion 11a because the stress that acts on the interface between each of the in-plane conductors 8c3 and the ceramic layer 2a and the interface between each of the in-plane conductors 8c3 and the resin insulating layer 3c is reduced.

### Sixth Embodiment

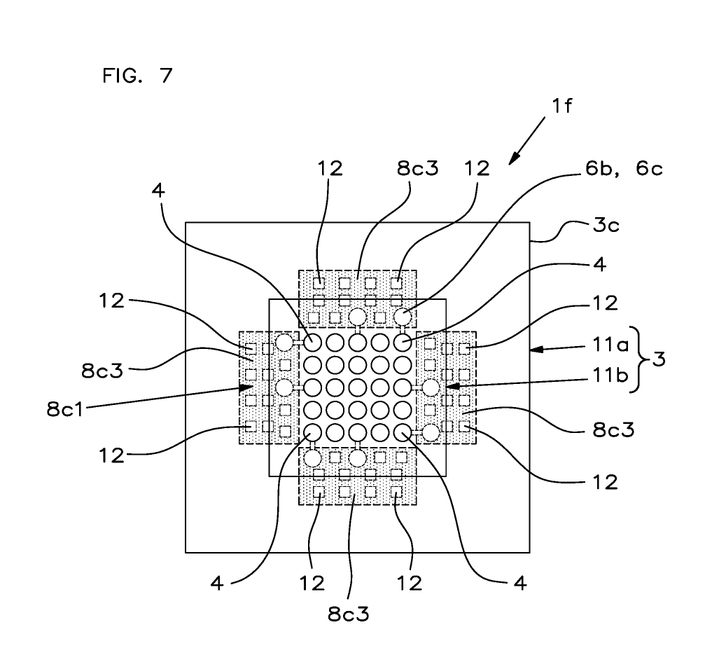

A multilayer circuit board if according to a sixth embodiment of the present disclosure will be described with reference to FIG. 7. In this regard, FIG. 7 is a plan view of the multilayer circuit board if and is a drawing corresponding to FIG. 2.

The multilayer circuit board if according to the present embodiment is different from the multilayer circuit board 1e according to the fifth embodiment described with reference to FIG. 6 in that, as shown in FIG. 7, each of the in-plane conductors 8c3 is configured to have a mesh pattern by being provided with a plurality of through holes 12 penetrating the in-plane conductor 8c3 in the thickness direction. Other configurations are the same as those of the multilayer circuit board 1e according to the fifth embodiment and, therefore, are indicated by the same reference numerals, and explanations thereof will not be provided.

In the case where each of the in-plane conductors 8c3 is provided with a plurality of through holes 12, as described above, the resin of the resin insulating layer 3c enters each through hole 12 in the in-plane conductor 8c3 so as to set up pillars of the resin during formation of the resin multilayer body 3. Then, peeling of each of the in-plane conductors 8c3 is reduced because the stress that acts on the interface between the resin insulating layer 3c and the in-plane conductor 8c3 and the interface between the ceramic layer 2a and the in-plane conductor 8c3 is relaxed by the pillars.

### Seventh Embodiment

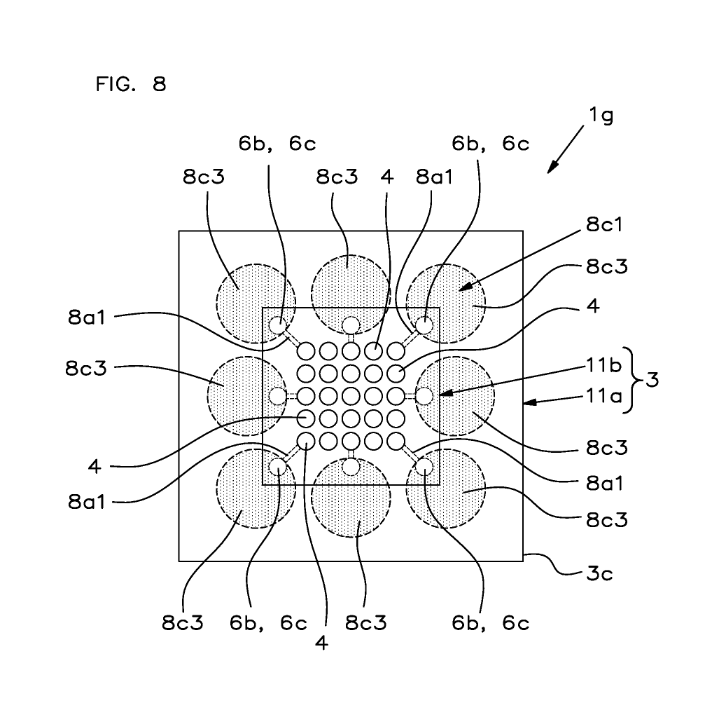

A multilayer circuit board 1g according to a seventh embodiment of the present disclosure will be described with reference to FIG. 8. In this regard, FIG. 8 is a plan view of the multilayer circuit board 1g and is a drawing corresponding to FIG. 2.

The multilayer circuit board 1g according to the present embodiment is different from the multilayer circuit board 1c according to the third embodiment described with reference to FIG. 4 in that, as shown in FIG. 8, each of the in-plane conductors 8c3 is configured to have a circular shape in plan view. Other configurations are the same as those of the multilayer circuit board 1c according to the third embodiment and, therefore, are indicated by the same reference numerals, and explanations thereof will not be provided.

Each of the in-plane conductors 8c3 in the above-described third embodiment is configured to have a rectangular shape in plan view. In such a case, in each of the in-plane conductors 8c3, the stress (residual stress) that acts on the interface between the in-plane conductor 8c3 and the ceramic layer 2a or the resin insulating layer 3c concentrates on four corner portions and, thereby, peeling of the in-plane conductors 8c3 occurs easily while the four corner portions serve as the base points. Then, interfacial peeling between the in-plane conductor 8c3 and the ceramic layer 2a and between the in-plane conductor 8c3 and the resin insulating layer 3c can be reduced by making the in-plane conductor 8c3 have a circular shape because the residual stress can be dispersed into the entire peripheral portion of the in-plane conductor 8c3.

(Modified Example of In-Plane Conductor 8c3)

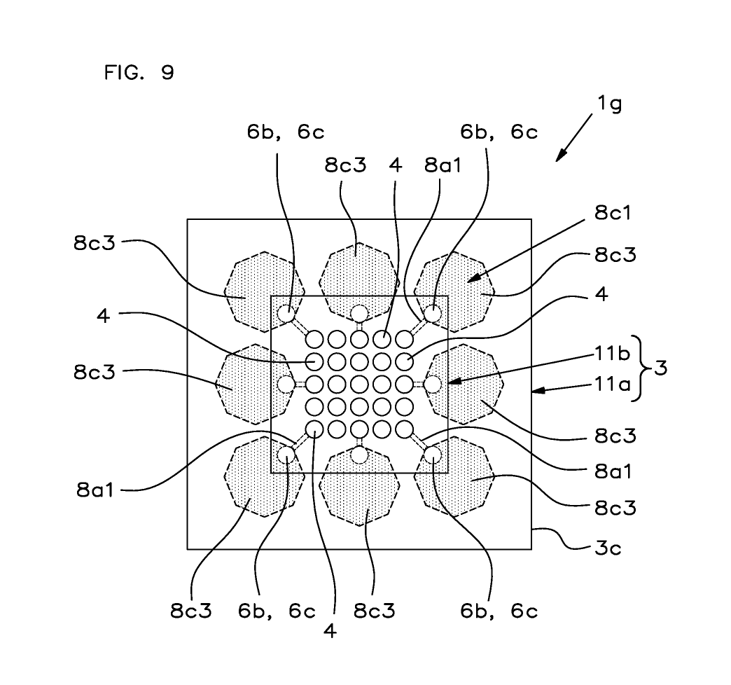

A modified example of the in-plane conductor 8c3 according to the present embodiment will be described with reference to FIG. 9. In this regard, FIG. 9 is a diagram showing a modified example of the in-plane conductor 8c3.

In the seventh embodiment, the case where each of the in-plane conductors 8c3 is configured to have a circular shape in plan view is described. However, for example, each of the in-plane conductors 8c3 may be configured to have a polygonal shape in plan view (octagonal shape in the present modified example). In this case, the stress (residual stress) that acts on each corner portion can be reduced compared with the case where each of the in-plane conductors 8c3 has a rectangular shape in plan view. Consequently, regarding each of the in-plane conductors 8c3, interfacial peeling between the in-plane conductor 8c3 and the resin insulating layer 3c and between the in-plane conductor 8c3 and the ceramic layer 2a can be reduced.

### Eighth Embodiment

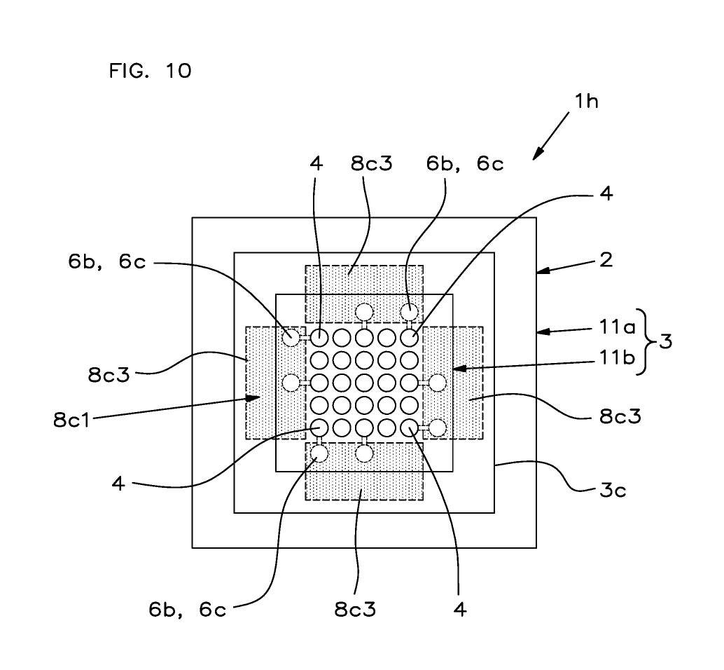

A multilayer circuit board 1h according to an eighth embodiment of the present disclosure will be described with reference to FIG. 10. In this regard, FIG. 10 is a plan view of the multilayer circuit board 1h and is a drawing corresponding to FIG. 2.

The multilayer circuit board 1h according to the present embodiment is different from the multilayer circuit board 1e according to the fifth embodiment described with reference to FIG. 6 in that, as shown in FIG. 10, the resin multilayer body 3 is configured to have an area in plan view smaller than the area of the ceramic multilayer body 2 in plan view. Other configurations are the same as those of the multilayer circuit board 1e according to the fifth embodiment and, therefore, are indicated by the same reference numerals, and explanations thereof will not be provided.

In this case, the resin multilayer body 3 is configured to have an area in plan view smaller than the area of the ceramic multilayer body 2 by making the area of the first multilayer portion 11a of the resin multilayer body 3 in plan view smaller than the area of the ceramic multilayer body 2 in plan view.

The residual stress in the multilayer circuit board 1h due to cure shrinkage of the resin multilayer body 3 is in proportion to the area of the resin multilayer body 3 in plan view. Consequently, interfacial peeling between the ceramic multilayer body 2 and the resin multilayer body 3 and warping of the multilayer circuit board 1h can be reduced by making the area of the resin multilayer body 3 in plan view smaller than the area of the ceramic multilayer body 2 because the residual stress in the multilayer circuit board 1h is reduced compared with the case where the areas of the two multilayer bodies 2 and 3 in plan view are equalized.

### Ninth Embodiment

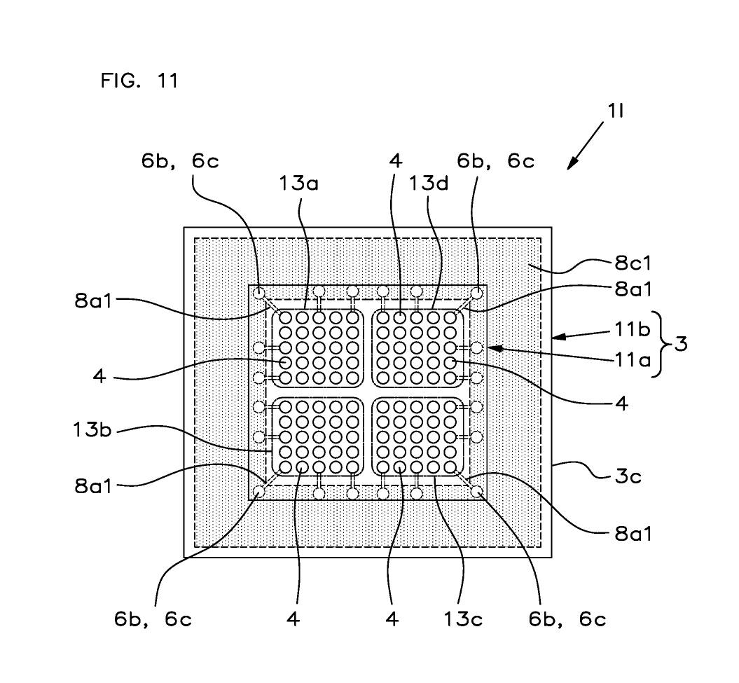

A multilayer circuit board 1i according to a ninth embodiment of the present disclosure will be described with reference to FIG. 11. In this regard, FIG. 11 is a plan view of the multilayer circuit board 1i and is a drawing corresponding to FIG. 2.

The multilayer circuit board 1i according to the present embodiment is different from the multilayer circuit board 1a according to the first embodiment described with reference to FIG. 1 and FIG. 2 in that, as shown in FIG. 11, a probe card using the multilayer circuit board 1i is configured to be able to electrically inspect a plurality of semiconductor elements 13a to 13d at a time by increasing the total number of the upper surface electrodes 4 disposed on the resin multilayer body 3. Other configurations are the same as those of the multilayer circuit board 1a according to the first embodiment and, therefore, are indicated by the same reference numerals, and explanations thereof will not be provided.

In this case, in order to electrically inspect the plurality of semiconductor elements 13a to 13d at a time, a total of four groups of upper surface electrodes 4 are disposed on the upper surface of the resin multilayer body 3, where upper surface electrodes 4 in the first embodiment (refer to FIG. 2) are specified as one group. Consequently, the same effects as the multilayer circuit board 1a according to the first embodiment are exerted and, in addition, the multilayer circuit board 1i capable of electrically inspecting the plurality of semiconductor elements 13a to 13d at a time can be provided.

### Tenth Embodiment

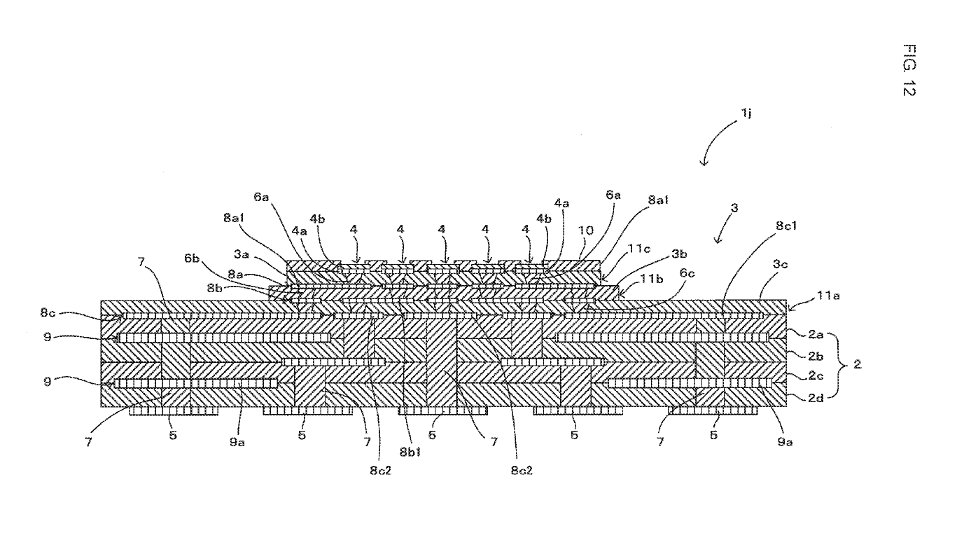

A multilayer circuit board 1j according to a tenth embodiment of the present disclosure will be described with reference to FIG. 12. In this regard, FIG. 12 is a sectional view of the multilayer circuit board 1j.

The multilayer circuit board 1j according to the present embodiment is different from the multilayer circuit board 1a according to the first embodiment described with reference to FIG. 1 and FIG. 2 in that, as shown in FIG. 12, the resin multilayer body 3 further includes a third multilayer portion 11c (corresponding to “another multilayer portion” in the present disclosure) stacked on the second multilayer portion 11b, and the resin multilayer body 3 is configured to have a pyramid shape, in which the first multilayer portion 11a, the second multilayer portion 11b, and the third multilayer portion 11c are configured such that the area of the upper side layer is smaller than the area of the lower side layer in plan view. Other configurations are the same as those of the multilayer circuit board 1a according to the first embodiment and, therefore, are indicated by the same reference numerals, and explanations thereof will not be provided.

In this case, the resin insulating layer 3c, which is the lowermost layer of the resin multilayer body 3, constitutes the first multilayer portion 11a, the resin insulating layer 3b, which is a layer disposed on the resin insulating layer 3c, constitutes the second multilayer portion 11b, and the third insulating layer 3a, which is the uppermost layer, constitutes the third multilayer portion 11c.

Regarding the multilayer circuit board 1j provided with the rewiring structure therein, in the central portion of the resin multilayer body 3 in plan view, the wiring density has to become higher from the first multilayer portion 11a toward multilayer portions 11b and 11c on the upper layer side, whereas the upper layer has a larger empty space in the peripheral portion.

By the way, in order to reduce interfacial peeling between the resin multilayer body 3 and the ceramic multilayer body 2 and warping of the multilayer circuit board 1j, it is effective to decrease the volume of the resin multilayer body 3 or decrease the area of each of the multilayer portions 11a, 11b, and 11c in plan view.

Then, in the present embodiment, it is utilized that the empty space in the peripheral portion of the resin multilayer body 3 on the upper layer side is larger than the empty space on the lower layer side in the rewiring structure. Regarding the area of each of the multilayer portions 11a, 11b, and 11c in plan view, the area of the upper layer is made to become smaller than the area of the lower layer and, thereby, the resin multilayer body 3 is configured to have a pyramid shape. Consequently, the volume of the resin multilayer body 3 can decrease, the residual stress in the multilayer circuit board 1j due to cure shrinkage of the resin multilayer body 3 can be reduced and, in addition, the stress that acts on the peripheral portion of the interface serving as a base point of interfacial peeling between the ceramic multilayer body 2 and the resin multilayer body 3 can be reduced. Therefore, interfacial peeling between the resin multilayer body 3 and the ceramic multilayer body 2 and warping of the multilayer circuit board 1j can be reduced by reducing the residual stress in the multilayer circuit board 1j and the residual stress that acts on the interface. In this regard, in the configuration, the resin multilayer body 3 may be configured to have a pyramid shape by further disposing a plurality of multilayer portions on the third multilayer portion 11c.

Meanwhile, the present disclosure is not limited to the above-described embodiments, and various modifications other than those described above can be made within the bounds of not departing from the gist of the disclosure. For example, in each of the above-described embodiments, the number of layers of the resin insulating layers 3a to 3c constituting each of the multilayer portions 11a, 11b, and 11c of the resin multilayer body 3 may be changed appropriately.

In this regard, the solder resist 10 disposed on the resin multilayer body 3 is not always necessary.

Also, the multilayer circuit board may be formed by combining the configurations of the above-described embodiments.

The present disclosure can be applied to various multilayer circuit boards in which a resin multilayer body is stacked on a ceramic multilayer body.

1a to 1j multilayer circuit board

2 ceramic multilayer body

2a to 2d ceramic layer

3 resin multilayer body

3a to 3c resin insulating layer

4 upper surface electrode

5 lower surface electrode

8c wiring layer

8c1, 8c3 in-plane conductor

11a first multilayer portion

11b second multilayer portion

11c third multilayer portion (another multilayer portion)

12 through hole

1. A multilayer circuit board comprising:
a ceramic multilayer body having a plurality of ceramic layers stacked; and
a resin multilayer body stacked on the ceramic multilayer body and having a plurality of resin insulating layers stacked,
wherein a peripheral portion of the resin multilayer body is thinner than a central portion of the resin multilayer body.

2. The multilayer circuit board according to claim 1,
wherein the resin multilayer body includes a first multilayer portion and a second multilayer portion stacked on a center of the first multilayer portion, wherein in the first multilayer portion, the plurality of resin insulating layers and a wiring layer having an in-plane conductor are stacked, and
the wiring layer is arranged between adjacent ones of the resin insulating layers and, the in-plane conductor is arranged in the peripheral portion of the resin multilayer body in a plan view.

3. The multilayer circuit board according to claim 1,
wherein the resin multilayer body includes a first multilayer portion and a second multilayer portion stacked on a center of the first multilayer portion, wherein in the first multilayer portion, one of the resin insulating layers and the wiring layer having the in-plane conductor are stacked, and
the wiring layer is arranged between the ceramic multilayer body and one of the resin insulating layers and, the in-plane conductor is arranged in the peripheral portion of the resin multilayer body in a plan view.

4. The multilayer circuit board according to claim 2,
wherein the first multilayer portion has a rectangular shape in a plan view, and
the in-plane conductor is arranged between two adjacent corner portions of four corner portions of the first multilayer portion in a plan view.

5. The multilayer circuit board according to claim 2,
wherein the in-plane conductor is configured to have a mesh pattern by being provided with a plurality of through holes penetrating the in-plane conductor in a thickness direction of the in-plane conductor.

6. The multilayer circuit board according to claim 2, wherein the wiring layer has a plurality of in-plane conductors.

7. The multilayer circuit board according to claim 6, wherein at least a pair of in-plane conductors of the plurality of in-plane conductors are arranged at positions symmetric with respect to a central point of the first multilayer portion in a plan view.

8. The multilayer circuit board according to claim 2,
wherein the in-plane conductor is a ground electrode or a power supply electrode.

9. The multilayer circuit board according to claim 6, wherein parts of the plurality of in-plane conductors are ground electrodes and remainders are power supply electrodes.

10. The multilayer circuit board according to a claim 2, wherein the in-plane conductor is configured to have a circular shape in a plan view.

11. The multilayer circuit board according to claim 2, wherein the in-plane conductor is configured to have a polygonal shape in a plan view.

12. The multilayer circuit board according to claim 1, wherein the resin multilayer body in a plan view is configured to have an area smaller than an area of the ceramic multilayer body in a plan view.

13. The multilayer circuit board according to claim 2, wherein the resin multilayer body further includes another multilayer portion stacked on the second multilayer portion, and the resin multilayer body is configured to have a pyramid shape, wherein the first multilayer portion, the second multilayer portion, and the another multilayer portion are configured such that an area of an upper layer of the resin multilayer body is smaller than an area of a lower layer of the resin multilayer body in a plan view.

14. The multilayer circuit board according to claim 1, further comprising a plurality of upper surface electrodes disposed on an upper surface of the resin multilayer body and a plurality of lower surface electrodes disposed on a lower surface of the ceramic multilayer body so as to correspond to the plurality of upper surface electrodes and connected to the corresponding upper surface electrodes,
wherein wiring structures in the ceramic multilayer body and the resin insulating layer are configured such that a pitch between adjacent ones of the lower surface electrodes becomes larger than a pitch between adjacent ones of the upper surface electrodes.

15. An inspection apparatus comprising the multilayer circuit board according to claim 1 and configured to inspect a semiconductor.

16. The multilayer circuit board according to claim 3,
wherein the first multilayer portion has a rectangular shape in a plan view, and
the in-plane conductor is arranged between two adjacent corner portions of four corner portions of the first multilayer portion in a plan view.

17. The multilayer circuit board according to claim 3,
wherein the in-plane conductor is configured to have a mesh pattern by being provided with a plurality of through holes penetrating the in-plane conductor in a thickness direction of the in-plane conductor.

18. The multilayer circuit board according to claim 4,
wherein the in-plane conductor is configured to have a mesh pattern by being provided with a plurality of through holes penetrating the in-plane conductor in a thickness direction of the in-plane conductor.

19. The multilayer circuit board according to claim 3, wherein the wiring layer has a plurality of in-plane conductors.

20. The multilayer circuit board according to claim 4, wherein the wiring layer has a plurality of in-plane conductors.
